(19) United States
(12) Patent Application Publication
(10) Pub. No.: US 2007/0201594 A1
(43) Pub. Date: Aug. 30, 2007

(54) Phase Locked Loop (Pll) Circuit, Its Phasing Method And Operation Analyzing Method

(75) Inventor: Genichi Fujiwara, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Mitsubishi Electric Corporation, Tokyo (JP)

(21) Appl. No.: 10/593,713

(22) PCT Filed: May 17, 2004
(86) PCT No.: PCT/JP04/06639

§ 371 Date: Sep. 21, 2006

(51) Int. Cl. H03D 3/24

(52) U.S. Cl. 375/376

(57) ABSTRACT

A phase locked loop (PLL) circuit including a phase comparator 2 that compares a phase of a reference clock signal with that of a comparison clock signal to produce a phase comparison signal having three-level outputs of a high voltage (H) level, a low voltage (L) level, and a reference level, and outputs an H or L level signal for duration corresponding to a detected phase difference or outputs a reference level signal when there is no phase difference detected; a level shifter 3 that serves to hold the rectangular waveform of the phase comparison signal from the phase comparator 2; a voltage controlled oscillator (VCO) 4 that advances the phase upon receipt of the H level signal and delay the phase upon receipt of the L level signal; and a frequency divider 5 that divides a frequency of an oscillation clock from the VCO 4 to produce a comparison clock signal.

### TECHNICAL FIELD

The present invention relates to a Phase Locked Loop (PLL) circuit that produces a clock signal corresponding to a phase difference between a reference clock signal and a comparison clock signal, and also to a phase synchronization method for the circuit.

### BACKGROUND ART

A patent document 1 (Unexamined Patent Publication No. 2004-40227) discloses a conventional PLL circuit, for example.

The conventional PLL circuit is equipped with a phase comparator for comparing phase to produce an output signal having a phase difference proportional to a time difference between the duration of a rectangular wave signal having a high voltage level and that of a rectangular wave signal having a low voltage level. The duration of the rectangular wave signal having the high voltage level is equal to that of the rectangular wave signal having the low voltage level when there is no phase difference. The conventional PLL circuit is configured so that the loop filter once required is omitted and a waveform shaping circuit for holding rectangular waveform of the output signal from the phase comparator is replaced for the loop filter omitted.

A Voltage Controlled Oscillator (VCO) is designed on the assumption that the voltage-frequency variation characteristic of the VCO becomes an odd function when frequency variation is a function of voltage. Patent Document 1: Unexamined Patent Publication No. 2004-40227

### DISCLOSURE OF THE INVENTION

### Problems to be Solved by the Invention

The thus configured conventional PLL circuit requires a VCO whose voltage-frequency characteristic becomes an odd function when the frequency variation is a function of voltage. On an actual VCO, such a characteristic exists only partially in the area, so that there is no choice but using such a limited area.

Another problem is that a VCO is costly when such a characteristic exists in a large part of the area, which results in an increase in circuit costs.

Another problem is that the phase comparator described in the patent document 1, which is not a commonly used component, has to be specially designed, which accordingly pushes up the design costs.

Still another problem is that the conventional PLL circuit uses the phase comparator, and accordingly an output frequency from the VCO varies even in a stationary mode when the phase is synchronized.

An object of this invention is to attain a low cost PLL circuit that outputs a clock signal whose frequency varies little.

### MEANS TO SOLVE THE PROBLEMS

A phase locked loop (PLL) circuit according to this invention may be characterized by including:

a phase comparator that receives a reference clock signal and a comparison clock signal, compares a phase of the reference clock signal with a phase of the comparison clock signal, produces a rectangular wave signal having three voltage levels corresponding to phase differences, and outputs the rectangular wave signal;

a level shifter that receives the rectangular wave signal outputted from the phase comparator, shifts a voltage level of the rectangular wave signal, and outputs the rectangular wave signal whose voltage level has been shifted;

a voltage controlled oscillator (VCO) that receives the rectangular wave signal outputted from the level shifter, and outputs a clock signal whose frequency corresponds to the voltage level of the rectangular wave signal; and

a frequency divider that divides the frequency of the clock signal outputted from the VCO by N (N is a counting number), and feeds back a signal whose frequency is divided to the phase comparator as the comparison clock signal.

The phase comparator may be characterized by comparing the phase of the reference clock signal with the phase of the comparison clock signal on every cycle of the reference clock signal, and producing the rectangular wave signal having three levels, a high voltage level, a low voltage level, and a reference level.

The phase comparator may be characterized by producing a rectangular wave signal having a high voltage level by making duration of the rectangular wave signal having the high voltage level proportional to a phase difference when the comparison clock signal has the phase difference caused by a phase lag, and producing a rectangular wave signal having a low voltage level by making duration of the rectangular wave signal having the low voltage level proportional to the phase difference when the comparison clock signal has the phase difference caused by a phase lead, and outputting a reference level signal without outputting the rectangular wave signal having the high or low voltage level when there is no phase difference.

The level shifter may be characterized by converting three voltage levels, a voltage level of the rectangular wave signal having the high voltage level, a voltage level of the rectangular wave signal having the low voltage level, and a voltage level of the reference level, to a voltage level for controlling a VCO.

The level shifter may be characterized by including a plurality of resistors connected in series; and a switch that produces the voltage level for controlling a VCO by switching connections of the plurality of resistors based on the three voltage levels.

The phase comparator may be characterized by comparing the phase of the reference clock signal with the phase of the comparison clock signal on every cycle of the reference clock signal, and producing the rectangular wave signal having three levels, a high voltage level, a low voltage level, and a reference level.

The VCO may be characterized by having an arbitrary voltage-frequency characteristic.

The PLL circuit may be characterized in that a mathematical model is used as a principle of operation of the PLL circuit, the mathematical model expressing a response from the PLL circuit by a numeric sequence.

A phase synchronization method for a phase locked loop (PLL) circuit according to this invention may be characterized by including:

receiving a reference clock signal and a comparison clock signal, comparing a phase of the reference clock signal with a phase of the comparison clock signal, producing a rectangular wave signal having three voltage levels corresponding to phase differences, and outputting the rectangular wave signal;

receiving the rectangular wave signal, shifting a voltage level of the rectangular wave signal, and outputting the rectangular wave signal whose voltage level has been shifted;

receiving the rectangular wave signal whose voltage level has been shifted, and outputting a clock signal whose frequency corresponds to the voltage level of the rectangular wave signal; and

dividing a frequency of the clock signal by N (N is a counting number), and feeding back a signal whose frequency is divided to the phase comparator as the comparison clock signal.

The phase synchronization method for a PLL circuit may be characterized by comparing the phase of the reference clock signal with the phase of the comparison clock signal on every cycle of the reference clock signal, and producing the rectangular wave signal having three levels, a high voltage level, a low voltage level, and a reference level.

An operation analysis method for a phase locked loop (PLL) circuit according to this invention may be characterized by an operation analysis method for a PLL circuit including:

a phase comparator that receives a reference clock signal and a comparison clock signal, compares a phase of the reference clock signal with a phase of the comparison clock signal, produces a rectangular wave signal having a predetermined voltage level, duration of which corresponds to a phase difference, and outputs the rectangular wave signal;

a voltage controlled oscillator (VCO) that receives a signal outputted from the phase comparator, and outputs a clock signal whose frequency corresponds to a voltage level of the signal; and

a frequency divider that divides a frequency of a clock signal outputted from the VCO by N (N is a counting number), and feeds back a signal whose frequency is divided to the phase comparator as the comparison clock signal,

The operation analysis method may be characterized by including analyzing an operation for the phase difference between the reference clock signal and the compression clock signal by using a mathematical model expressed below:
θₙ=(1−((G·T)/(2π−N)))ⁿθ
n: a counting number
π: a circle ratio
G: a fixed number corresponding to the voltage-frequency characteristic of the VCO
T: an oscillation cycle of the reference clock signal
N: a frequency divisor (a counting number) of the frequency divider
θ: a phase difference at time 0
θₙ: a phase difference at time nT

### BEST MODE FOR CARRYING OUT THE INVENTION

### Embodiment 1

A description is given below of a Phase Locked Loop (PLL) circuit 100 with reference to figures. A PLL circuit, also called a phase synchronization loop or the like, is a circuit to generate an output signal whose phase is not different from that of an input signal.

In FIG. 1, an input terminal 1 is a terminal from which a reference clock signal FR is inputted.

A phase comparator 2 compares the phases of incoming two signals, and outputs a phase difference detection signal PD corresponding to a phase difference between the signals. The phase comparator 2 outputs a rectangular wave signal having a high voltage (H) level and a rectangular wave signal having a low voltage (L) level. The phase comparator 2 outputs as the phase difference detection signal PD a rectangular wave corresponding to the phase difference and having duration of the H or L level rectangular wave signal proportional to the phase difference. The phase compactor 2 outputs reference level voltage when there is no phase difference.

A level shifter 3 is a waveform-shaping device to hold rectangular waveform of the phase difference detection signal PD from the phase comparator 2.

A voltage controlled oscillator (VCO) 4, which has a control terminal, is an oscillator that can change oscillation frequency using the direct current voltage of a direct current signal DC applied to the control terminal. The VCO 4 is an oscillator to generate an oscillation clock signal CL that is N times the frequency of a reference clock signal (N is a counting number).

A frequency divider 5 is a clock frequency divider to divide the frequency of the oscillation clock signal CL by N and output a comparison clock signal FP to the phase comparator 2.

An output terminal 6 is a terminal that outputs the oscillation clock signal CL.

FIG. 2 is a diagram illustrating an example of implementation of the level shifter 3.

In FIG. 2, SW1 and SW2 denote analog switches to switch the contacts of signals based on the output level of a rectangular wave signal from the phase comparator 2. The SW1 is a switch that turns ON only when the phase difference detection signal PD is the H level rectangular wave signal. The SW2 is a switch that turns ON only when the phase difference detection signal PD is the L level rectangular wave signal. In other situations, both the SW1 and the SW2 are OFF. The SW1 and the SW2 never turn ON at the same time.

R1, R2, R3 and R4 denote resisters (or resistance values thereof) to set out the voltage level of the direct current signal DC to be inputted to the VCO 4. The R1, the R2, the R3 and the R4 are connected in series and to which a voltage Vcc is applied.

The following shows the switching conditions of the SW1 and the SW2 depending on the output level of the rectangular wave signal from the phase comparator 2. The voltage level at that time of the direct current DC to be inputted to the VCO 4 is described below.

When the SW1 is ON and the SW2 is OFF, then Voltage Level=Vcc×((R3+R4)/(R1+R3+R4)) with a high voltage level because the R2 is bypassed. A signal having this high voltage level (or the voltage level thereof) will be referred to hereinafter as V_{H}.

When the SW1 is OFF and the SW2 is ON, then Voltage Level=Vcc×((R4)/(R1+R2+R4)) with a low voltage level because the R3 is bypassed. A signal with this low voltage level (or the voltage level thereof) will be referred to hereinafter as V_{L}.

When the SW1 is OFF and the SW2 is OFF, then Voltage Level=Vcc×((R3+R4)/(R1+R2+R3+R4)) with a reference voltage between V_{H} and V_{L} because the R1 through the R4 are all connected. A signal with this reference voltage (or the voltage level thereof) will be referred to hereinafter as Vₙ(V_{H}>Vₙ>V_{L}).

FIG. 3 is a diagram illustrating the voltage-frequency characteristic of the VCO 4.

In FIG. 3, the horizontal axis shows the input voltage v of the direct current signal DC to the VCO 4. The input voltage v ranges from 0V to Vcc V.

The vertical axis shows an output frequency f of the oscillation clock signal CL from the VCO 4. A frequency f₀ is assumed to be 1/N of a frequency fr of the reference clock signal FR. When the input voltage v is 0V, then the output frequency f becomes a frequency f₀−df. When the input voltage v is Vcc V, then the output frequency f does not however become a frequency f₀+df. When the V_{H} and the V_{L} are appropriately chosen, then the following may be obtained.

The Vₙ is the reference voltage whose output frequency f becomes the frequency f₀.

The V_{L} is the low voltage whose output frequency f becomes a frequency f₀−Δf.

The V_{H} is the high voltage whose output frequency f becomes a frequency f₀+Δf.

A relation among the three voltage levels is V_{H}>Vₙ>V_{L}. It is not always true, however, that V_{H}−Vₙ=Vₙ−V_{L}.

Referring to FIG. 3, it is apparent from the graph showing a characteristic that frequency variation from the frequency f₀ of the output frequency f becomes:
g(V_{H})=−g(V_{L})=Δf, g(Vₙ)=0
when it is the function g(v) of the input voltage v.

That is, Δf=G (G is a fixed number).

Level setting is made in advance so that the level shifter 3 generates voltages such as V_{H}, Vₙ, and V_{L}. More specifically, the level shifter 3 set the levels so that a difference (Δf) between an output frequency to the VCO corresponding to an H level output and a clock frequency of a reference voltage and a difference (−Δf) between an output frequency to the VCO corresponding to an L level output and the clock frequency of the reference voltage are equal in absolute value but different in sign.

With regard to frequency, the oscillation clock signal CL in a steady state may be expressed as:
f₀=N×fr,fr=fp
where f₀ denotes the frequency of the oscillation clock signal CL, fr denotes the frequency of the reference clock signal FR, and fp denotes the frequency of the comparison clock signal FP.

FIG. 4 is a diagram showing the concept of a basic operation of the phase comparator 2 and the level shifter 3.

The horizontal axis shows time. The vertical direction shows a signal waveform of the reference clock signal FR, a signal waveform of the comparison clock signal FP, an output waveform of the phase difference detection signal PD from the phase comparator 2, and the voltage of the direct current signal DC from the level shifter 3 or the input voltage v to the VCO 4.

FIG. 4 shows the case of a phase difference of θ between the comparison clock signal FP and the reference clock signal FR. The phase comparator 2 detects this phase difference θ. A phase lag of the comparison clock signal FP is denoted by −θ and a phase lead of the comparison clock signal FP is denoted by +θ.

The phase comparator 2, when detecting a phase lag, outputs the rectangular wave signal having the voltage Vcc during a period from time t1 to time t2 to advance the phase (in order to turn the SW1 ON). The level shifter 3, upon receipt of the rectangular wave signal having the voltage Vcc, turns the SW1 ON, so that the voltage is changed to V_{H}, to output the direct current signal DC. Operations like this are repeated in series until the n-th cycle (n is a counting number) where a phase difference θₙ (n is a counting number) is processed, which attains a synchronous phase finally at time t3 of the n-th cycle (FIG. 4 shows a case of n=1).

The phase comparator 2 outputs a signal having a voltage Vcc/2 with a synchronous phase. The level shifter 3, upon receipt of a signal having the voltage Vcc/2, turns the SW1 and the SW2 both OFF, so that the voltage is changed to Vₙ, to output the direct current signal DC. Alternatively, the level shifter 3 keeps the SW1 and SW2 OFF, and outputs the direct current signal DC whose voltage is kept to a voltage Vₙ.

The phase comparator 2, when detecting a phase lead, outputs the rectangular wave signal having a voltage 0 (GND) during a period from time t4 to time t5 to delay the phase (in order to turn the SW2 ON). The level shifter 3, upon receipt of the rectangular wave signal having the voltage 0, turns the SW2 ON, so that the voltage is changed to V_{L}, to output the direct current signal DC. Operations like this are repeated in series until the n-th cycle (n is a counting number) where the phase difference θₙ (n is a counting number) is processed, which attains a synchronous phase finally at time t6 of the n-th cycle (FIG. 4 shows a case of n=1).

FIG. 5 is a diagram illustrating the waveform of a detection signal having a phase difference of θ between the comparison clock signal FP and the reference clock signal FR when detected by the phase comparator 2.

Referring to FIG. 5, the horizontal axis shows time. The vertical direction shows the voltage of the current signal DC, that is, the voltage level of the input voltage v to the VCO 4.

T (T=1/fr) denotes duration of one cycle of the reference clock signal FR.

Vₙ denotes reference voltage for reference. The Vₙ is the same as that shown in FIG. 3 and FIG. 4.

V_{L} is low voltage corresponding to an L level portion. The V_{L} is the same as that shown in FIG. 3 and FIG. 4. The V_{L} is a signal for delaying the phase.

V_{H} is high voltage corresponding to an H level portion. The V_{H} is the same as that shown in FIG. 3 and FIG. 4. The V_{H} is a signal for advancing the phase.

The V_{H} is convex and the V_{L} is concave in shape.

In FIG. 5, the V_{H} rises at the middle of a cycle (half the cycle time or T/2) and holds the high voltage during a period of (θ/2π)T and then returns to the reference voltage.

The V_{L} holds the low voltage during a period of (θ/2π)T before the middle of the cycle (T/2) and then returns to the reference voltage at the middle of the cycle (T/2).

With reference to FIG. 4, the V_{H} and the V_{L} are outputted to the same positions as where there are phase differences, respectively. Like the case of FIG. 5, however, when the phase comparator 2 outputs the phase difference detection signal PD with T/2 as a core, then the V_{H} and the V_{L} are outputted after and before T/2, respectively. The phase may thus be adjusted within one cycle T without fail.

Duration between the V_{H} and the V_{L} is equivalent to the period of (θ/2π)T. In other words, the duration between the V_{H} and the V_{L} is proportional to the phase difference θ. For this reason, the frequency becomes f₀+Δf or f₀−Δf of the oscillation clock signal CL during the period of (θ/2π)T. Consequently, the phase of the oscillation clock signal CL is advanced or delayed by an amount proportional to θ.

A description is now given of a phase synchronization method for the PLL circuit 100 with reference to an operational flowchart of FIG. 6.

Inputting Step S1

Initially, the reference clock signal FR inputted through the input terminal 1 for the reference clock signal is inputted to the phase comparator 2. The oscillation clock signal CL from the VCO 4 is divided by N in the frequency divider 5, and then inputted to the phase comparator 2 as the comparison clock signal FP.

Phase Comparing Step S2

Next, with the phase comparator 2, the phase of an incoming reference clock signal FR is compared with the phase of an incoming comparison clock signal FP. The phase comparator 2 then outputs, according to a phase difference, a rectangular wave of the H or L level rectangular wave signal whose duration is proportional to the phase difference as the phase difference detection signal PD.

The phase comparator 2, when detecting a phase lag of the comparison clock signal FP, outputs the H level rectangular wave signal having Vcc V to turn the SW1 ON in order to advance the phase. The duration of the H level rectangular wave signal is proportional to the phase difference. The period of duration is equivalent to the period of (θ/2π)T.

The phase comparator 2 outputs a signal having Vcc/2 V when there is no phase difference.

The phase comparator 2, when detecting a phase lead of the comparison clock signal FP, outputs the L level rectangular wave signal having 0V (GND) to turn the SW2 ON in order to delay the phase. The duration of the L level rectangular wave signal is proportional to the phase difference. The period of the duration is equivalent to the period of (θ/2π)T.

Now, the output of the phase comparator 2 is assumed as follows.

The H level is almost equivalent to the power supply voltage of Vcc, which is sufficiently higher than Vcc/2 in electric potential. The L level is almost equivalent to a ground potential GND=0V, which is sufficiently lower than Vcc/2 in electric potential.

The standard level is almost equivalent to Vcc/2, which is sufficiently lower than Vcc but sufficiently higher than GND in electric potential.

This setting may be achieved by selecting the values of the R1, the R2, the R3, and the R4 (e.g., R1, R4<R2, R3).

Level Shifting Step S3

The phase difference detection signal PD outputted from the phase comparator 2 is inputted to the level shifter 3.

Now, the level shifter 3 is configured as shown in FIG. 2, for example. The SW1 of FIG. 2 is now assumed to operate on receiving an almost Vcc in electric potential and short the R2, but not to operate on receiving any other values in electric potential. The SW2 of FIG. 2 is also assumed to operate on receiving an almost GND in electric potential and short the R3, but not to operate on receiving any other values in electric potential.

The level shifter 3 eliminates overshoot or undershoot from the phase difference detection signal PD, converts the H level to:
V_{H}=Vcc×((R3+R4)/(R1+R3+R4)),
the L level to:
V_{L}=R4/(R1+R2+R4),
the reference level to:
Vₙ=(R3+R4)/(R1+R2+R3+R4),
and inputs a result to the VCO 4 as a frequency controlled voltage for the VCO 4.

Oscillation Step S4

The VCO 4 converts the duration of the H level rectangular wave signal to an amount of phase to be eliminated during the period of one cycle, and then oscillates. The VCO 4 also converts the duration of the L level rectangular wave signal to an amount of phase to be added during the period of one cycle, and then oscillates.

More specifically, frequency controlled voltages to be inputted to the VCO 4 of one cycle T include the amount of phases to be added or eliminated during the one cycle as the duration of the H or L level rectangular wave signal. The VCO 4 reads this duration and oscillates the oscillation clock signal CL whose phase has been controlled according to the duration.

FIG. 4 shows the operation described above. When the phase of the comparison clock signal FP lags behind the phase of the reference clock signal FR, then the level shifter 3 outputs the V_{H} during duration proportional to the corresponding phase difference. When the phase of the comparison clock signal FP leads the phase of the reference clock signal FR, the level shifter 3 then outputs the V_{L} during duration proportional to the corresponding phase difference. When neither the V_{H} nor the V_{L} is outputted, then the level shifter 3 keeps outputting the Vₙ.

When there is no phase difference between the comparison clock signal FP and the reference clock signal FR, or good phase synchronization is achieved, then the Vₙ is also outputted.

Outputting Step S5

The oscillation clock signal CL outputted from the VCO 4 diverges into a signal to be outputted to outside via the output terminal 7 as an output from the PLL circuit and a signal inputted to the frequency divider 5.

Frequency-dividing Step S6

The oscillation clock signal CL is divided by N in the frequency divider 5, and then fed back to the phase comparator 2 as the comparison clock signal FP.

According to the PLL circuit of this embodiment, an output from the phase comparator 2 becomes the stationary reference level voltage of Vcc/2 after the phase is synchronized, and an output from the level shifter receiving this voltage also becomes the stationary reference level of Vₙ of the VCO 4. It may be expected therefore that an output frequency from the VCO 4 or an output frequency from the PLL circuit is a clock output with little variation.

With this embodiment, the PLL operation is not described by a transfer function, but treated as a numeric sequence of an adjustment amount of phase of one cycle of the reference clock signal FR. FIG. 5 shows a waveform of the detection signal when the phase comparator 2 detects a phase lag or lead of θ between the comparison clock signal FP and the reference clock signal FR, for example.

With reference to the H level portion and the L level portion of this waveform when Vₙ is a reference line, the H level portion is a phase lead element and the L level portion is a phase lag element as shown in FIG. 5 based on the characteristics of the VCO 4 of FIG. 3.

More specifically, when a phase lag of θ of the comparison clock signal FP behind the phase of the reference clock signal FR is detected, then the phase of the comparison clock signal FP may be advanced by an amount proportional to the phase difference θ between the reference clock signal FR and the comparison clock signal FP by the phase lead element shown in FIG. 5. When a phase lead of 0 of the comparison clock signal FP ahead of the phase of the reference clock signal FR is detected, then the phase of the comparison clock signal FP may be delayed by an amount proportional to the phase difference θ between the reference clock signal FR and the comparison clock signal FP by the phase lag element shown in FIG. 5.

Thus, the PLL circuit according to this embodiment is equipped with the phase comparator 2 that compares the phase to produce an output signal having three-level outputs of the H level rectangular wave signal, the L level rectangular wave signal, and the reference level, and outputs the H or L level signal having duration corresponding to a detected phase difference or outputs a standard level voltage when there is no phase difference detected.

The PLL circuit according to this embodiment is also equipped with the level shifter 3 that serves to hold rectangular waveform of the output signal from the phase comparator 2.

The level shifter 3 is to set the levels of the output voltages (Vₙ, V_{H}, V_{L}) so that the difference (Δf) between the output frequency (f₀+Δf) of the VCO 4 corresponding to the H level output V_{H} and the clock frequency (f₀) of the reference voltage Vₙ and the difference (Δf) between the output frequency (f₀−Δf) of the VCO 4 corresponding to the L level output V_{L} of the level shifter 3 and the clock frequency (f₀) of the reference voltage Vₙ are equal in absolute value but different in sign (|Δf|=|−Δf|).

The PLL circuit according to this embodiment is to perform operation analysis and designing by the numeric sequence where the phase difference of one cycle of the reference clock signal is a unit of measurement. This is explained as follows.

An explanation is now given for a mathematical model that describes these circuit operations quantitatively.

When a phase difference between the reference clock signal FR and the comparison clock signal FP is θ at time t=0, then a phase difference ψ (t) at time t>0 is given by the following expression.

$$ψ ( t ) = θ - \frac{1}{N} \cdot {\int }_{0}^{t} g ( v ( x ) ) ⅆ x \qquad [ Expression 1 ]$$

When θₙ₋₁ is a phase difference between the reference clock signal FR and the comparison clock signal FP (a result of the phase of the reference clock signal FR minus the phase of the comparison clock signal FP) at time t=(n−1)T(n=1,2,3, . . . ), the voltage v(t) to be inputted to the VCO 4 during the period of (n−1)T≦t≦nT is given below. When a step function U(t):

$$U ( t ) = \{ \begin{matrix}1 , & t > 0 \\ 0 , & t < 0\end{matrix} \qquad [ Expression 2 ]$$

is used, and

$${τ}_{n} = ( n - 1 ) T + \frac{\vert {θ}_{n - 1} \vert}{2 π} T \qquad [ Expression 3 ]$$

is defined, then the following expression is given when the phase of the comparison clock signal FP lags behind the phase of the reference clock signal FR (θₙ₋₁>0).

$$v ( t ) = {V}_{H} \cdot U [ t - ( n - 1 ) T ] - {V}_{H} \cdot U ( t - {τ}_{n} ) + {V}_{n} \cdot U ( t - {τ}_{n} ) - {V}_{n} \cdot U ( t - nT ) \qquad [ Expression 4 ]$$

This expression is the same as the following expression:

$$v ( t ) = \{ \begin{matrix}{V}_{H} , & ( n - 1 ) T < t \leq {τ}_{n} \\ {V}_{n} , & {τ}_{n} < t \leq nT\end{matrix} \qquad [ Expression 5 ]$$

in value.

When the v(t) is plugged into g(v), and g is converted to the function of time t, then the following expression is obtained.

$$g ( t ) = \{ \begin{matrix}g ( {V}_{H} ) = Δ f = G , & ( n - 1 ) T < t \leq {τ}_{n} \\ g ( {V}_{n} ) = 0 , & {τ}_{n} < t \leq nT\end{matrix} \qquad [ Expression 6 ]$$

Likewise, when the phase of the comparison clock signal FP leads the phase of the reference clock signal FR(θₙ₋₁<0), then the following expression is obtained.

$$v ( t ) = {V}_{L} \cdot U [ t - ( n - 1 ) T ] - {V}_{L} \cdot U ( t - {τ}_{n} ) + {V}_{n} \cdot U ( t - {τ}_{n} ) - {V}_{n} \cdot U ( t - nT ) \qquad [ Expression 7 ]$$

This expression is the same as the following expression:

$$v ( t ) = \{ \begin{matrix}{V}_{L} , & ( n - 1 ) T < t \leq {τ}_{n} \\ {V}_{n} , & {τ}_{n} < t \leq nT\end{matrix} \qquad [ Expression 8 ]$$

in value.

When the v(t) is plugged into g(v), and g is converted to the function of time t, then the following expression is obtained.

$$g ( t ) = \{ \begin{matrix}g ( {V}_{L} ) = - Δ f = - G , & ( n - 1 ) T < t \leq {τ}_{n} \\ g ( {V}_{n} ) = 0 , & {τ}_{n} < t \leq nT\end{matrix} \qquad [ Expression 9 ]$$

Therefore, the amount of frequency variation g(t) when (n−1)T<t≦nT is given by the following expression including (θₙ₋₁>0) and (θₙ₋₁<0) together.

$$g ( t ) = \frac{{θ}_{n - 1}}{\vert {θ}_{n - 1} \vert} \cdot G \cdot \{ U ( t - ( n - 1 ) T ) - U ( t - {τ}_{n} ) \} \qquad [ Expression 10 ]$$

The phase difference θₙ when t=nT may be calculated by using this expression.

$$\begin{matrix}{θ}_{n} = Ψ ( nT ) \\ = θ - \frac{{θ}_{n - 1}}{\vert {θ}_{n - 1} \vert} \cdot \frac{G}{N} \cdot \\ [ {\sum }_{k = 1}^{n - 1} {\int }_{( k - 1 ) \cdot T}^{k \cdot T} [ \begin{matrix}U ( t - ( k - 1 ) \cdot T ) - \\ U ( t - {τ}_{k} )\end{matrix} ] ⅆ t ] - \\ \frac{{θ}_{n - 1}}{\vert {θ}_{n - 1} \vert} \cdot \frac{G}{N} \cdot \\ {\int }_{( n - 1 ) \cdot T}^{n \cdot T} [ U ( t - ( n - 1 ) \cdot T ) - U ( t - {τ}_{n} ) ] ⅆ t \\ = {θ}_{n - 1} - \frac{{θ}_{n - 1}}{\vert {θ}_{n - 1} \vert} \cdot \frac{G}{N} \cdot \\ {\int }_{( n - 1 ) \cdot T}^{n \cdot T} [ U ( t - ( n - 1 ) \cdot T ) - U ( t - {τ}_{n} ) ] ⅆ t\end{matrix} \qquad [ Expression 11 ]$$

The definite integration of this expression may be calculated as follows:

$${θ}_{n} = ( 1 - \frac{G \cdot T}{2 π \cdot N} ) \cdot {θ}_{n - 1} \qquad [ Expression 12 ]$$

which is a recurrence formula that expresses a geometric sequence.

Therefore, the following expression is the mathematic model of the phase difference variation of each cycle T.

$${θ}_{n} = {( 1 - \frac{G \cdot T}{2 π \cdot N} )}^{n} \cdot θ \qquad [ Expression 13 ]$$

The convergence condition of this sequence should be a lockup condition of the PLL circuit of this embodiment. In addition to this, the following expression:

$$0 < \frac{G \cdot T}{π \cdot N} < 4 \qquad [ Expression 14 ]$$

should be satisfied.

This means, in other words, the PLL circuit will surely be locked up regardless of the value of the initial phase difference θ (when time t=0) as long as the above condition is satisfied.

This also shows that the phase difference becomes 0 in the period of one cycle when GT/Nπ=2.

More specifically, the use of the mathematical model of this embodiment may provide a method of analyzing the operation of the PLL circuit, and at the same time, show a response operation of the PLL circuit of this embodiment to a step phase input. This also makes it possible to design the lockup time.

Thus, the PLL circuit according to this embodiment is characterized by having the phase comparator that compares the phase of the reference clock signal with the phase of the comparison clock signal on every cycle of the reference clock signal. The phase comparator outputs the rectangular wave signal having three levels of the high voltage level, the low voltage level, and the reference level. The duration of the rectangular wave signal having the high or low voltage level is proportional to the phase difference. The phase comparator does not output the rectangular wave signal having the high or low voltage level when there is no phase difference, but outputs the reference level.

The PLL circuit is also characterized by having the voltage-controlled oscillator (VCO) that outputs the clock signal having a frequency corresponding to the level of a voltage level applied. The PLL circuit is also characterized by feeding back the signal obtained by dividing the clock signal outputted from the VCO by N (N is a counting number) to the phase comparator as the comparison clock signal.

The PLL circuit is further characterized by having the level shifter that converts the voltage levels of the rectangular wave signal having the high voltage level, the rectangular wave signal having the low voltage level, and the reference level, which are outputted from the phase comparator, to the controlled voltage level as an appropriate input to the VCO.

The PLL circuit may thus be provided with the VCO having an arbitrary voltage-frequency characteristic.

In addition to this, the PLL circuit uses the mathematical model that describes the response of the PLL circuit by numeric sequence as the operation principle.

### INDUSTRIAL APPLICABILITY

As described above, the PLL circuit according to this embodiment, the phase comparator having the three-level outputs is a type called a “phase-frequency comparator” and commonly in an integrated circuit (IC). The use of such a general phase comparator may eliminate the need for designing a special comparator, so that the PLL circuit may be obtained with a reduction in design costs.

Once the phase is synchronized, only the stationary reference level voltages are inputted to the VCO, so that the output frequency from the PLL circuit has little variation.

When the phase convergence condition, i.e.,
|θₙ<ε [Expression 15]
(where ε is a maximum value of an acceptable phase difference when the phase is synchronized)
is determined, then the convergence speed is computable directly by n that satisfies this phase convergence condition. An advantageous feature of a conventional PLL circuit of n×T is maintained.

Further, with the convergence conditional expression of numeric sequence, the convergence area is twice that of the conventional PLL circuit, so that the PLL circuit with greater flexibility in circuit design may be obtained.

### BRIEF DESCRIPTION OF THE DRAWINGS

FIG. 1 It is a block diagram of a PLL circuit to explain a first embodiment of the present invention.

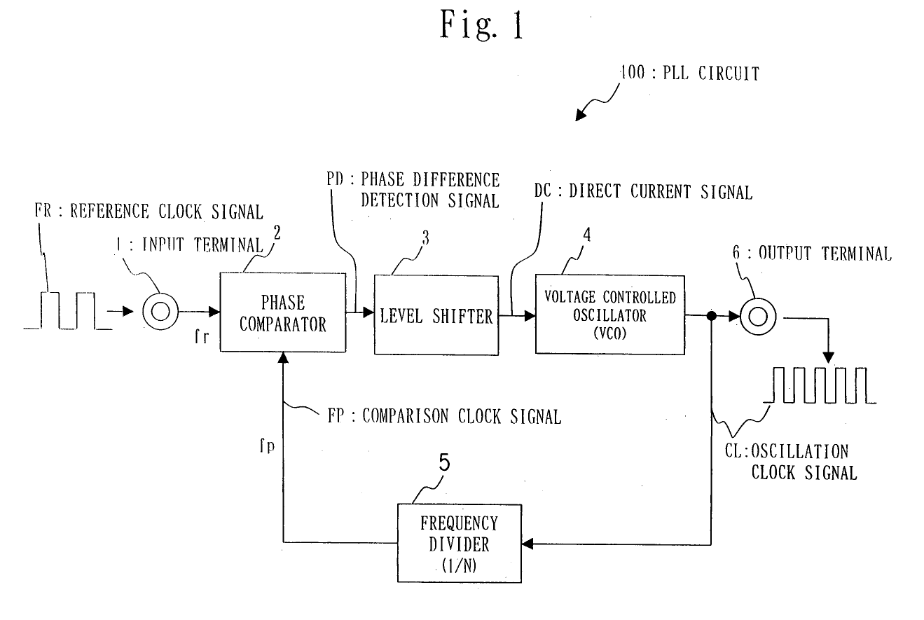

FIG. 2 It is a block diagram illustrating an example of implementation of a level shifter used in the first embodiment of the present invention.

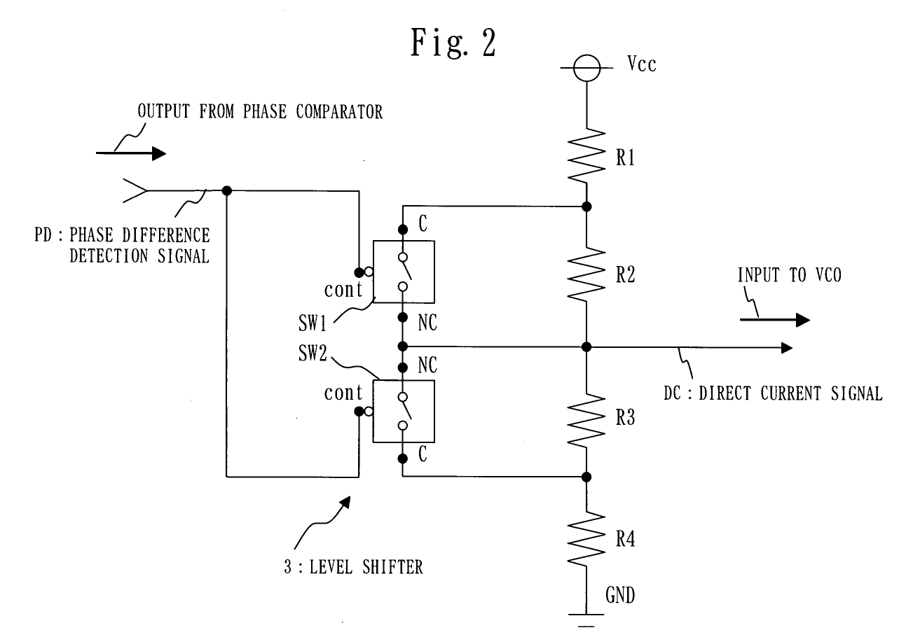

FIG. 3 It is a diagram illustrating a voltage-frequency characteristic of a VCO used in the PLL circuit according to the first embodiment of the present invention.

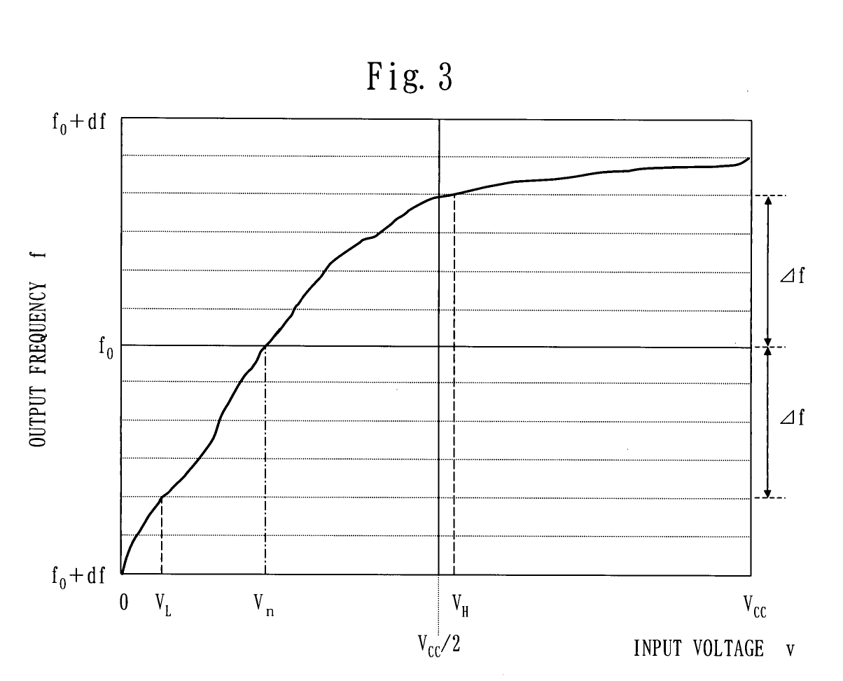

FIG. 4 It is a diagram illustrating a concept of the basic operations of a phase comparator and the level shifter used in the first embodiment of the present invention.

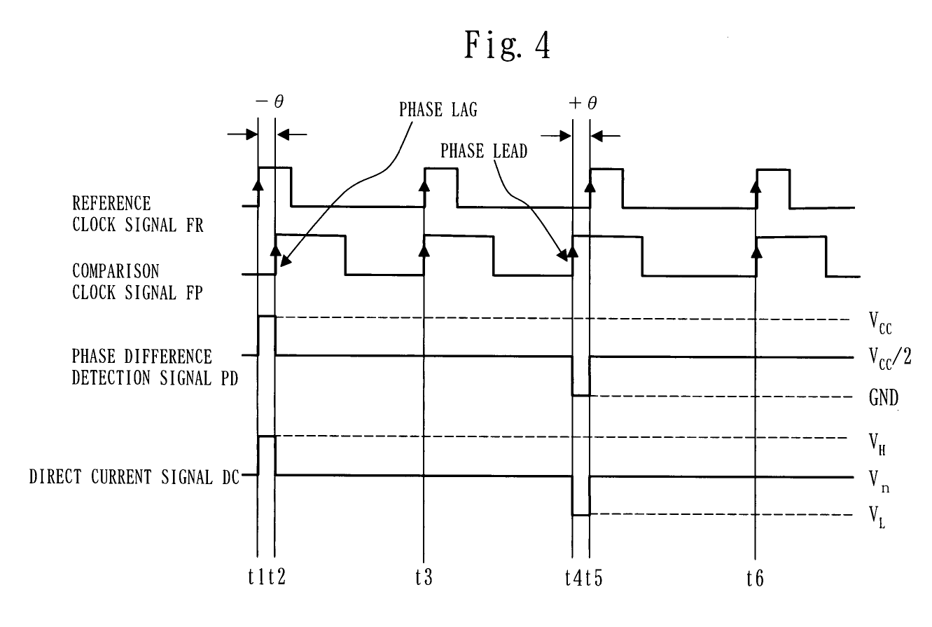

FIG. 5 It is a diagram to explain a mathematical model of the PLL circuit according to the first embodiment of the present invention.

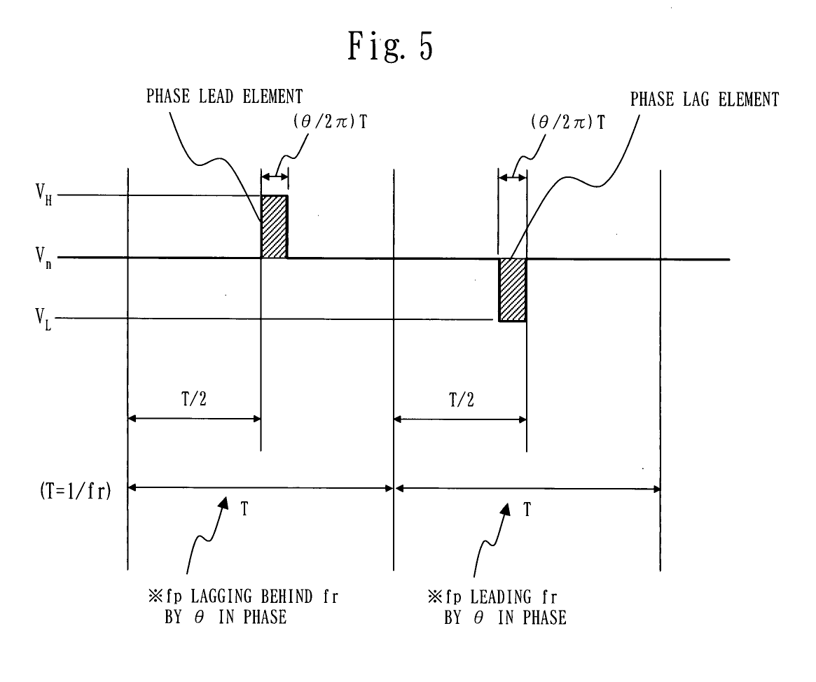

FIG. 6 It is a diagram illustrating a phase controlling method of the PLL circuit according to the first embodiment of the present invention.

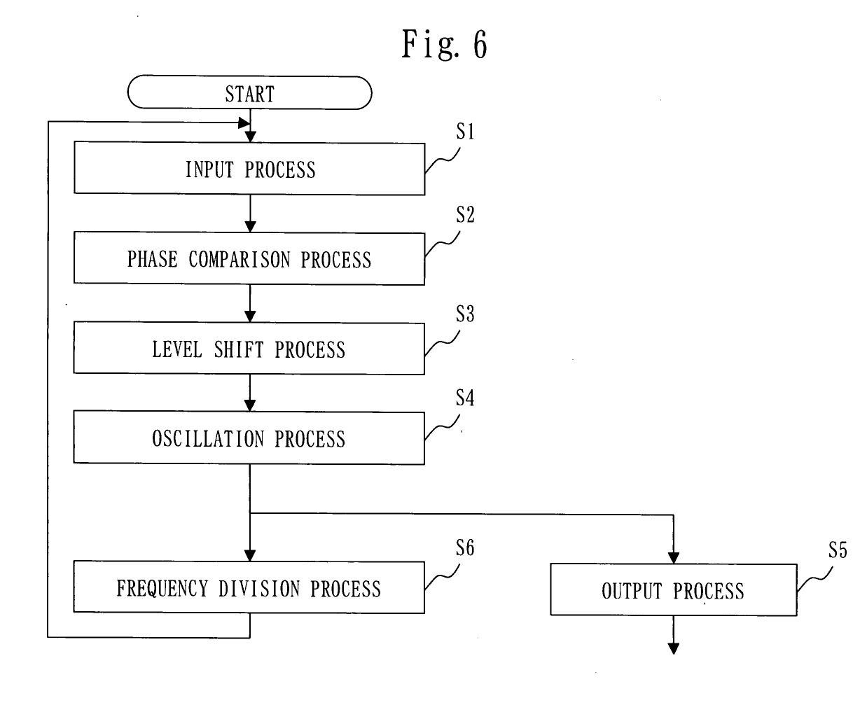

1. A phase locked loop (PLL) circuit comprising:
a phase comparator that receives a reference clock signal and a comparison clock signal, compares a phase of the reference clock signal with a phase of the comparison clock signal, produces a rectangular wave signal having three voltage levels corresponding to phase differences, and outputs the rectangular wave signal;
a level shifter that receives the rectangular wave signal outputted from the phase comparator, shifts a voltage level of the rectangular wave signal, and outputs the rectangular wave signal whose voltage level has been shifted;
a voltage controlled oscillator (VCO) that receives the rectangular wave signal outputted from the level shifter, and outputs a clock signal whose frequency corresponds to the voltage level of the rectangular wave signal; and
a frequency divider that divides the frequency of the clock signal outputted from the VCO by N (N is a counting number), and feeds back a signal whose frequency is divided to the phase comparator as the comparison clock signal.

2. The PLL circuit of claim 1, wherein the phase comparator compares the phase of the reference clock signal with the phase of the comparison clock signal on every cycle of the reference clock signal, and produces the rectangular wave signal having three levels, a high voltage level, a low voltage level, and a reference level.

3. PLL circuit of claim 2, wherein the phase comparator produces a rectangular wave signal having a high voltage level by making duration of the rectangular wave signal having the high voltage level proportional to a phase difference when the comparison clock signal has the phase difference caused by a phase lag, and produces a rectangular wave signal having a low voltage level by making duration of the rectangular wave signal having the low voltage level proportional to the phase difference when the comparison clock signal has the phase difference caused by a phase lead, and outputs a reference level signal without outputting the rectangular wave signal having the high or low voltage level when there is no phase difference.

4. The PLL circuit of claim 1, wherein the level shifter converts three voltage levels, a voltage level of the rectangular wave signal having the high voltage level, a voltage level of the rectangular wave signal having the low voltage level, and a voltage level of the reference level, to a voltage level for controlling a VCO.

5. The PLL circuit of claim 4, wherein the level shifter includes:
a plurality of resistors connected in series; and
a switch that produces the voltage level for controlling a VCO by switching connections of the plurality of resistors based on the three voltage levels.

6. The PLL circuit of claim 1, wherein the phase comparator compares the phase of the reference clock signal with the phase of the comparison clock signal on every cycle of the reference clock signal, and produces the rectangular wave signal having three levels, a high voltage level, a low voltage level, and a reference level.

7. The PLL circuit of claim 1, wherein the VCO has an arbitrary voltage-frequency characteristic.

8. The PLL circuit of claim 1, wherein a mathematical model is used as a principle of operation of the PLL circuit, the mathematical model expressing a response from the PLL circuit by a numeric sequence.

9. A phase synchronization method for a phase locked loop (PLL) circuit comprising:
receiving a reference clock signal and a comparison clock signal, comparing a phase of the reference clock signal with a phase of the comparison clock signal, producing a rectangular wave signal having three voltage levels corresponding to phase differences, and outputting the rectangular wave signal;
receiving the rectangular wave signal, shifting a voltage level of the rectangular wave signal, and outputting the rectangular wave signal whose voltage level has been shifted;
receiving the rectangular wave signal whose voltage level has been shifted, and outputting a clock signal whose frequency corresponds to the voltage level of the rectangular wave signal; and
dividing the frequency of the clock signal by N (N is a counting number), and feeding back a signal whose frequency is divided to the phase comparator as the comparison clock signal.

10. The phase synchronization method for a PLL circuit of claim 9, wherein the comparing the phases of the signals includes comparing the phases on every cycle of the reference clock signal, and the producing the rectangular wave signal includes producing the rectangular wave signal having three levels, a high voltage level, a low voltage level, and a reference level.

11. An operation analysis method for a phase locked loop (PLL) circuit, the PLL circuit including:
a phase comparator that receives a reference clock signal and a comparison clock signal, compares a phase of the reference clock signal with a phase of the comparison clock signal, produces a rectangular wave signal having a predetermined voltage level, duration of which corresponds to a phase difference, and outputs the rectangular wave signal;
a voltage controlled oscillator (VCO) that receives a signal outputted from the phase comparator, and outputs a clock signal whose frequency corresponds to a voltage level of the signal; and
a frequency divider that divides the frequency of the clock signal outputted from the VCO by N (N is a counting number), and feeds back a signal whose frequency is divided to the phase comparator as the comparison clock signal,
the operation analysis method comprising:
analyzing an operation for the phase difference between the reference clock signal and the compression clock signal by using a mathematical model expressed below:
θₙ=(1−((G·T)/(2π·N)))ⁿ·θ
n: a counting number
π: a circle ratio
G: a fixed number corresponding to the voltage-frequency characteristic of the VCO
T: an oscillation cycle of the reference clock signal
N: a frequency divisor (a counting number) of the frequency divider
θ: a phase difference at time 0
θₙ: a phase difference at time nT
